(19) United States
(12) Patent Application Publication
(10) Pub. No.: US 2002/0196687 A1
(43) Pub. Date: Dec. 26, 2002

(54) Methods and apparatus for analyzing and repairing memory

(76) Inventors: Anthony J. Sauvageau, Raleigh, NC (US); Michael A. Mullins, Durham, NC (US)

Correspondence Address: Michael G. Savage, Esquire, BURNS, DOANE, SWECKER & MATHIS, L.L.P., P.O. Box 1404, Alexandria, VA, 22313-1404, US

(21) Appl. No.: 10/164,513

(22) Filed: Jun. 6, 2002

Related U.S. Application Data
(60) Provisional application No. 60/296,793, filed on Jun. 8, 2001.

(51) Int. Cl. G11C 7/00

(52) U.S. Cl. 365/200

(57) ABSTRACT

Methods and apparatus for analyzing and repairing memory are presented. The method includes the step of determining if failed memory cells detected in at least a portion of memory must be repaired using only one of a number of types of memory spares or may be repaired using any of the number of types of memory spares. Failed memory cells that must be repaired using only one of the number of types of memory spares are repeatedly repaired, skipping any failed memory cells that may be repaired using any of the number of types of memory spares, until either no new errors that must be repaired are repaired and no failed memory cells are skipped or the memory is determined to not be repairable. At least one of any failed memory cells skipped when repairing failed memory cells that must be repaired is repaired. The steps of determining if failed memory cells must be repaired and repeatedly repairing failed memory cells that must be repaired are repeated whenever at least one skipped failed memory cell is repaired.

### RELATED APPLICATIONS

This application claims priority under 35 U.S.C. § 119(e) to U.S. Patent Application No. 60/296,793, entitled “Repair Analysis Algorithm Suitable for On-Chip Implementation”, filed on Jun. 8, 2001, the entire content of which is hereby incorporated by reference.

### BACKGROUND

What is described are methods and apparatus for analyzing and repairing memory. In particular, methods and apparatus for analyzing and repairing failed memory cells of memory having redundant memory circuitry are presented.

In the most general sense, memory can be defined as two-dimensional arrays of memory cells having a number of rows (M) and a number of columns (N). Each intersection of a row and a column produces one output bit of stored information. Often it is desirable to have more than one bit of information output from the memory at any given time. Two methods for accomplishing this are to either duplicate the entire array structure to provide the additional output bit, or to subdivide one dimension of the array (e.g., either in the M or N dimension) into various subdivisions, each subdivision providing one output bit each time the memory array is accessed.

Three variables, R, C, and I/O, may be used to describe the subdivided (typically written as R×C×IO). R and C may represent the number of rows and the number of columns in the array, respectively, and serve as inputs to the array. The I/O variable may represent the number of bits that are output from an “intersection” of a row and column in the array. In practice, the I/O bits are not formed at the intersection of a single row and column of the array. Instead, the I/O bits are formed by either a collection of intersections of a single row and multiple columns of the array that are accessed simultaneously, or by a collection of intersections of a single column and multiple rows of the array that are accessed simultaneously. How the I/O bits are formed depends upon whether rows or columns are subdivided to create the multiple I/Os for the array.

Conventional memory arrays contain redundant memory cells that are used to replace failed memory cells, largely to increase the manufacturing yields of memory. Since memory may be generally defined as two-dimensional arrays of rows and columns, it is convenient to also define the redundant cells as two-dimensional groups of spare rows and spare columns (or spare I/Os). The number of spare rows and columns (or I/Os) and their configurations can vary, but typically a memory array will be arranged to have either groups of spare rows and columns, or groups of spare rows and I/Os.

A spare row is capable of simultaneously replacing a number of columns and I/Os associated with a single row address of memory. Similarly, a spare column, if present, is capable of replacing a number of rows associated with a single column address of memory. Spare I/Os, if present, are capable of simultaneously replacing a number of columns associated with a particular I/O bit of memory. Typically, I/Os are oriented in a same direction as either the rows or columns of the memory array, and can thus be treated the same as the type of spare oriented in the same direction for purposes of failed memory cell replacement.

Conventional memory testing involves both an identification of all failed memory addresses in a memory array and an identification of which bit(s) of those memory addresses have failed. A typical memory test involves writing various data patterns into a memory, then reading and comparing the output of the memory with expected values or patterns. Mismatches between expected and actual read memory values are stored in an external memory map, typically located in the memory tester itself.

After all of the test patterns have been executed and the failed addresses (and bits) have been identified and stored, the tester may then perform a repair analysis on the stored error data to determine which failed address rows' and/or columns' (or I/Os) bits (or cells) will need to be replaced with available spare memory cells to make the memory fully operational. The failed memory information is typically analyzed at the end of all of the memory testing. This allows a repair routine to take all of the failed memory information into consideration in order to determine an optimal repair configuration that maximizes the operation of the memory and that uses the redundant memory cells in the most efficient manner. In addition, by taking all failed memory information into consideration at one time, certain un-repairable memory conditions may be identified early, and the memory discarded, before wasting valuable test and repair time on the un-repairable situation.

Limitations associated with most conventional testers require that the repair information be generated and used dynamically. This can reduce the overall memory yield by using the redundant memory cells inefficiently. These limitations have also made memory testing a most expensive and time consuming process in the development of faster and denser memory.

For example, conventional memory testers typically have a relatively slower processing clock speed than the operating frequency of the memory cells that they are used to test. The relatively slower clock speed makes it impossible to determine whether the memory under test will operate correctly at normal operating speeds. Also, collecting error information at the normal operating speed is not possible using these slower conventional testers. Consequently, the tester must be capable of storing large amounts of error data and then analyzing this large amount of data in a repair routine that is executed “off line”. With conventional testers, the error memory must be as large as the total expected number of failed bits. Moreover, as memory densities continue to increase, the already limited tester memory must also increase and the processing power of the tester must be increased in order to be able to process more complex repair routine solutions.

Another limitation associated with conventional testers is their typical limited I/O capability. As memory become more dense, the number of I/Os needed to test the memory must also increase. Testers that are I/O limited will not be able to test the entire memory at one time, requiring that the test program be partitioned into several smaller tests. The partitioning of the memory test leads to an overall increased test time, which contributes greatly to the costs associated with memory manufacture.

Memory designers have utilized built-in-self-test (or BIST) techniques to address some of these concerns. With BIST, a pattern generator for testing the memory is fabricated on the same semiconductor chip (or wafer) as the memory itself. This allows the BIST circuitry to test the memory “at speed”, eliminating the concerns of failing to detect errors as a result of testing memory at sub-operating speeds. In addition, BIST circuitry addresses the concerns associated with today's testers being I/O limited.

Still, limitations exist with conventional BIST techniques. For example, large amounts of error memory must still be incorporated into the BIST circuitry in order to store the failed memory information. Also, additional storage and processor resources must be incorporated into the memory to perform the repair routine processing. Because of space and processor limitations, only limited amounts of error storage and repair code can integrated into the BIST design. Consequently, conventional BIST techniques continue to use a “snapshot approach” for detecting failed memory locations. This requires that the repair routine process failed memory information “on the fly”, which, as discussed above, leads to an inefficient use of the redundant memory cells included on the memory chip.

There is thus a need for improved techniques for analyzing and repairing memory that will reduce the complexity of the repair routine to a much simpler task, and relieve the error storage requirements placed on memory testers.

### SUMMARY

Accordingly, one object is to provide a reduced complexity memory analysis and repair technique that can efficiently repair several smaller portions of memory at the same time. Another object is to provide a memory analysis and repair technique that enables the on-chip storage of all failed memory information in an efficient manner. Another object is to provide for at-speed analysis and generation of repair information for all failed memory information. Yet another object is to support the testing of memory having a large number of I/Os. Still another object is to detect certain un-repairable memory failure conditions early in execution of the repair routine. These objects are addressed by methods and apparatus to analyze and repair the failed memory cells of a memory.

According to one aspect, a method for analyzing and repairing memory includes the step of determining if failed memory cells detected in at least a portion of memory must be repaired using only one of a number of types of memory spares or may be repaired using any of the number of types of memory spares. Failed memory cells that must be repaired using only one of the number of types of memory spares are repeatedly repaired, skipping any failed memory cells that may be repaired using any of the number of types of memory spares, until either no new errors that must be repaired are repaired and no failed memory cells are skipped or the memory is determined to not be repairable. At least one of any failed memory cells skipped when repairing failed memory cells that must be repaired is repaired. The steps of determining if failed memory cells must be repaired and repeatedly repairing failed memory cells that must be repaired are repeated whenever at least one skipped failed memory cell is repaired.

According to a related aspect, a first type of the plurality of types of memory spares is capable of repairing one of a row and a column portion of memory and a second complementary type of the plurality of types of memory spares is capable of repairing the other of the row and column portions of memory.

According to another related aspect, failed memory cells that must be repaired include failed memory cells in a respective row or column portion of memory having a total number of failed memory cells that exceeds a number of available complementary type memory spares.

According to yet another related aspect, the at least a portion of memory is defined by logically dividing the memory into a number of analysis blocks, each analysis block completely including at least one of each type of the plurality of types of memory spares.

According to yet another related aspect, the at least a portion of memory is defined by logically dividing each analysis block into a number of sub-blocks, each sub-block extending over an area of the respective analysis block corresponding to a range of memory cells each of the plurality of types of memory spares are capable of repairing.

According to yet another related aspect, the method further includes the step of storing failed memory cell information for each sub-block as a separate addressable entry in memory.

According to yet another related aspect, the failed memory cell information for each sub-block is stored in a portion of the memory being analyzed and repaired.

According to yet another related aspect, each addressable entry in memory corresponds to an error storage table for a respective sub-block, each error storage table having row and column entries for storing information related to a number of failed memory cells detected in respective row and column portions of memory.

According to yet another related aspect, the method further includes the step of reading the information related to the number of failed memory cells detected in respective row and column portions of memory from at least one error storage table stored in memory. The failed memory cells detected in the at least a portion of memory are located in sub-blocks corresponding to the at least one error storage table from which the information related to the number of failed memory cells is read.

According to yet another related aspect, the method further includes the step of performing each of the steps of the method on separate portions of the memory until either all failed memory cells detected in the memory have been repaired or the memory is determined to not be repairable.

According to yet another related aspect, the performing of each of the steps of the method on separate portions of the memory occurs at the same time for each separate portion.

According to yet another related aspect, the step of repeatedly repairing failed memory cells that must be repaired using only one of the plurality of types of memory spares includes the step of determining if a row or column entry in the at least one error storage table is empty or if an error identified by the row or column entry has been repaired. If neither the row or column entry is empty nor the identified error has been repaired, then it is determined if the identified error must be repaired. Otherwise, it is determined if a next row or column entry in the at least one error storage table is empty or if an error identified by next the row or column entry has been repaired. If the identified error must be repaired, then it is determined if a spare of the only one of the plurality of types of memory spares is available. Otherwise, the step of repairing the identified error is skipped and it is determined if a next row or column entry in the at least one error storage table is empty or if an error identified by next the row or column entry has been repaired. If a spare of the only one of the plurality of types of memory spares is available, then the identified error is repaired with a spare of the only one of the plurality of types of memory spares and it is determined if a next row or column entry in the at least one error storage table is empty or if an error identified by next the row or column entry has been repaired. Otherwise, the memory is determined to not be repairable. The step of determining if a row or column entry in the at least one error storage table is empty or if an error identified by the row or column entry has been repaired is repeated until all row and column entries in the at least one error storage table have been processed.

According to yet another related aspect, the step of repairing at least one of any failed memory cells skipped when repairing failed memory cells that must be repaired includes the step of repairing only a first detected failed memory cell of the at least one of any skipped failed memory cells.

According to yet another related aspect, the step of repairing only a first detected failed memory cell includes the step of determining if a row or column entry in the at least one error storage table is empty. If the row or column entry is not empty, then it is determined if an error identified by the row or column entry has been repaired. Otherwise, it is determined if a next row or column entry in the at least one error storage table is empty. If the identified error has not been repaired, then it is determined if a first type of the plurality of types of memory spares is available. Otherwise, it is determined if a next row or column entry in the at least one error storage table is empty. If a first type of the plurality of types of memory spares is available, then the identified error is repaired with a spare of the first type. Otherwise, it is determined if a second complementary type of the plurality of types of memory spares is available. If a second type of the plurality of types of memory spares is available, then the identified error is repaired with a spare of the second type. Otherwise the memory is determined to not be repairable. The step of determining if a row or column entry in the at least one error storage table is empty is repeated until at least all row entries or all column entries in the at least one error storage table have been processed.

According to yet another related aspect, if it is determined that any row or column entry in the at least one error storage table is empty, next entries of the type that is empty need not be processed.

According to yet another related aspect, the row portion of memory includes at least one row of memory and the column portion of memory includes at least one column of memory.

According to yet another related aspect, the column portion of memory includes at least one input/output (I/O) device, the at least one I/O device providing an input and output path for at least one column of memory.

According to yet another related aspect, the step of repairing at least one of any failed memory cells skipped when repairing failed memory cells that must be repaired includes the step of determining which type of the plurality of types of memory spares is capable of repairing a greatest number of failed memory cells that may be repaired using any of the plurality of types of memory spares. The greatest number of failed memory cells is replaced with an available spare of the determined type.

According to yet another related aspect, prior to determining if failed memory cells detected in at least a portion of memory must be repaired, the method further includes the steps of determining if any of the plurality of types of memory spares in the at least a portion of memory is non-functional. Information related to non-functional memory spares is grouped together based on an arrangement of the plurality of types of memory spares in the at least a portion of memory.

According to yet another related aspect, the step of grouping together information related to non-functional memory spares includes the step of logically ORing together the information related to non-functional memory spares for a number of portions of the at least a portion of memory if the portions are capable of being repaired by at least one of a respective type of the plurality of types of memory spares.

It should be emphasized that the terms “comprises” and “comprising”, when used in this specification as well as the claims, are taken to specify the presence of stated features, steps or components; but the use of these terms does not preclude the presence or addition of one or more other features, steps, components or groups thereof.

### BRIEF DESCRIPTION OF THE DRAWINGS

The above objects, features, and advantages will become more apparent in light of the following detailed description in conjunction with the drawings, in which like reference numerals identify similar or identical elements, and in which:

FIG. 1 illustrates an exemplary memory array with redundant circuitry;

FIG. 2 illustrates a portion of the exemplary memory array shown in FIG. 1, and depicts a portion of the memory referred to as an analysis block;

FIG. 3 illustrates a flow diagram of an exemplary repair analysis routine; and

FIGS. 4A and 4B illustrate a flow diagram of an exemplary repair routine for processing the information generated by the repair analysis routine shown in FIG. 3.

### DETAILED DESCRIPTION

Preferred embodiments are described below with reference to the accompanying drawings. In the following description, well-known functions and/or constructions are not described in detail to avoid obscuring the description in unnecessary detail.

### Exemplary Memory Architecture

Before describing the analysis and repair technique in detail, it will be helpful to first describe an exemplary memory architecture upon which the technique may be applied. Taking a spare-centric view of a memory array, spare rows and columns (or I/Os) may be arranged at regular intervals throughout the memory array. The activation of the spare rows and columns (or I/Os) are typically controlled by a fuse, but other means of activation are commonly known. When a fuse is “blown”, the corresponding spare row or column (or I/O) is activated and the appropriate memory address to be replaced is programmed. A fuse may be “blown” in a variety of ways including, but not limited to, laser cutting and the activation of certain electrical signals.

Typically, fuses are relatively large as compared to the spare memory cells they activate, so any given fuse may often be used to activate and replace several rows or columns (or I/Os) at one time. With such arrangements, the groups of spare rows or columns activated and programmed by a given fuse may be viewed from an analysis and repair standpoint as a signal entity. This grouping of spare rows and columns may be exploited by the analysis and repair routine to achieve a degree of compression and efficiency in the identity and replacement of failed memory cells.

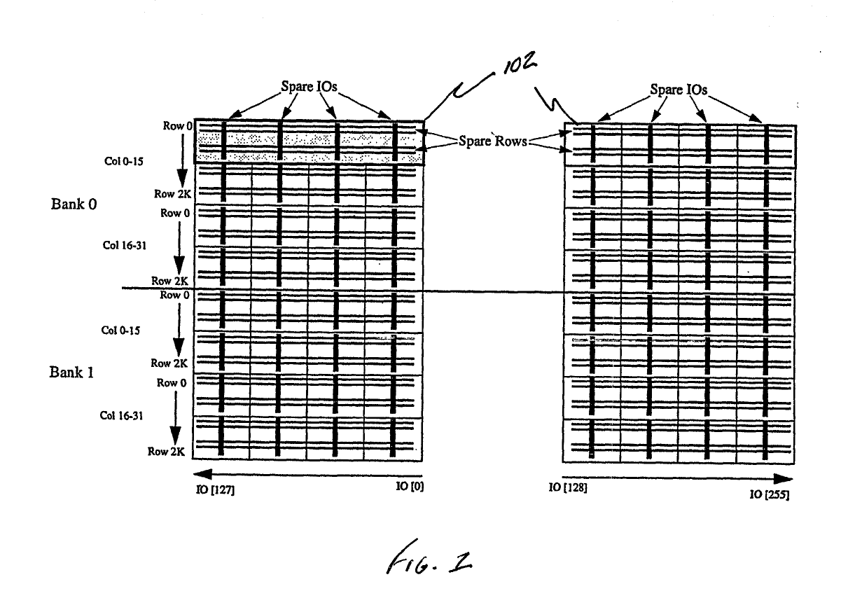

FIG. 1 depicts an exemplary memory array with redundant circuitry. The exemplary array includes two banks of memory cells, Bank 0 and Bank 1. Each bank of memory cells includes an array of thirty-two columns (Cols. 0-15 and 16-31) and 4096 rows (two sets of rows of 2K cells each). The memory banks are divided into portions each having 128 I/Os (IO[0]-IO[127] and IO[128]-IO[255]). Spare I/Os and rows are arranged at regular intervals throughout the array. As described above, a memory array including redundant circuitry having spare columns and rows could be used as well.

The memory array is logically divided into several portions referred to as an analysis block 102. The size and shape of an analysis block 102 is preferably chosen such that it defines a smallest portion of the memory array that completely contains at least one spare I/O (or column) and at least one spare row. The analysis and repair routine is preferably defined to operate on an analysis block 102 basis. In the exemplary memory architecture shown, sixteen analysis blocks are shown. It will be understood that the memory array may be logically partitioned into any number of analysis blocks.

Defining an analysis block 102 such that the spare memory cells in the analysis block are independent of the spare memory cells in other analysis blocks leads to further efficiencies in the repair and analysis routine, although such an arrangement is not strictly required. For example, by ensuring that the spare I/Os and rows in a given analysis block do not cross an analysis block boundary, the analysis and repair routine is capable of analyzing and repairing the various analysis blocks of the memory array independently and in parallel.

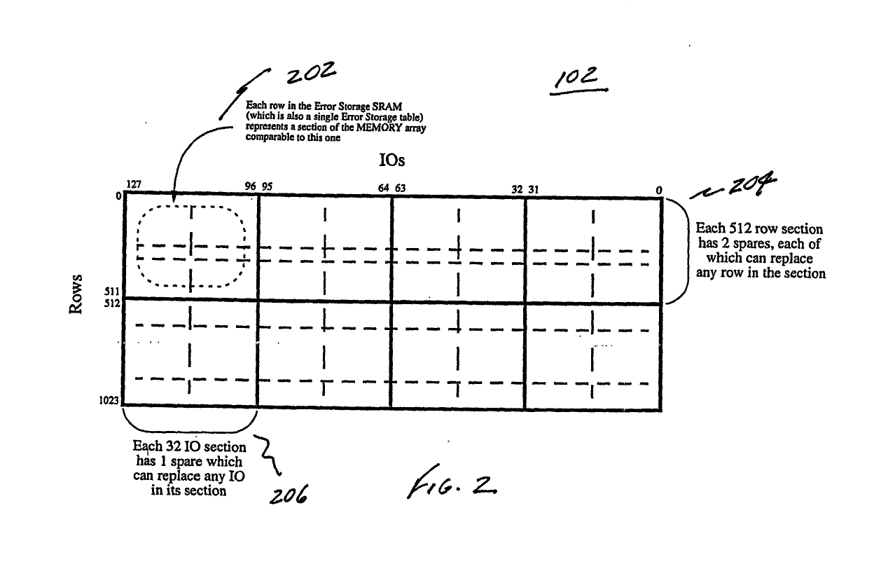

FIG. 2 illustrates the highlighted analysis block 102 shown in FIG. 1 in greater detail. As can be seen from the figure, each analysis block in the example is defined to include four I/O spares and four row spares. The analysis block 102 may be further logically divided into smaller portions referred to as sub-blocks 202. The analysis block shown in FIG. 2 has eight such sub-blocks 202. The sub-block sizes are preferably chosen such that the distance the sub-block extends in the row and I/O (or column) dimensions corresponds to the range of memory cells the row and I/O (or column) spares are capable of replacing.

According to the example shown, each sub-block 202 includes one I/O spare that can replace any of thirty-two I/Os in an I/O section 206, and two row spares that can replace any of 512 rows in the block. The sub-blocks are arranged into two rows of four sub-blocks each, the rows being referred to as a set 204. Preferably, the failed memory cell information for each sub-block is stored as a separate row entry in an error storage (ES) SRAM (not shown). Each row entry in the ES SRAM may also be referred to as an error storage table. A number of ES SRAMs may be used to store the failed memory cell information depending on the size of the memory array and the configuration of array's redundant circuitry. Techniques for storing the failed memory cell and repair information are described in the copending U.S. patent application Ser. No. 10/______, titled “Methods and Apparatus for Storing Memory Test Information”, filed on May 31, 2002, and having a common assignee as this application.

### Analysis Routine

Having described an exemplary memory architecture, a routine for analyzing the failed memory cells of a memory array will now be presented. The following terms used in the analysis routine (and the repair routine as well) are defined.

| | |
|---|---|
| Must: | A failed memory cell (or error) or group of errors that can be |
| | repaired in only one manner-either by replacing the error or |
| | group of errors with a spare row or with a spare I/O |
| | (or column). |
| Fixed: | A flag used to control flow of the routine. The flag should be |
| | set to “Y” whenever an error is repaired. |
| Skip: | Another flag used to control the flow of the routine. This flag |
| | should be set to “Y” whenever an error is detected, but not |
| | immediately repaired by the routine. |
| NG: | A flag used in the routine indicate that the memory array |
| | cannot be repaired. |
| Fix_Any: | A flag used in the routine to determine the types of error that |
| | are to be fixed immediately. If the flag is set to “Y”, any error |
| | encountered will be fixed, if possible. When set to “N”, only |
| | “Must” errors will be repaired by the routine. |

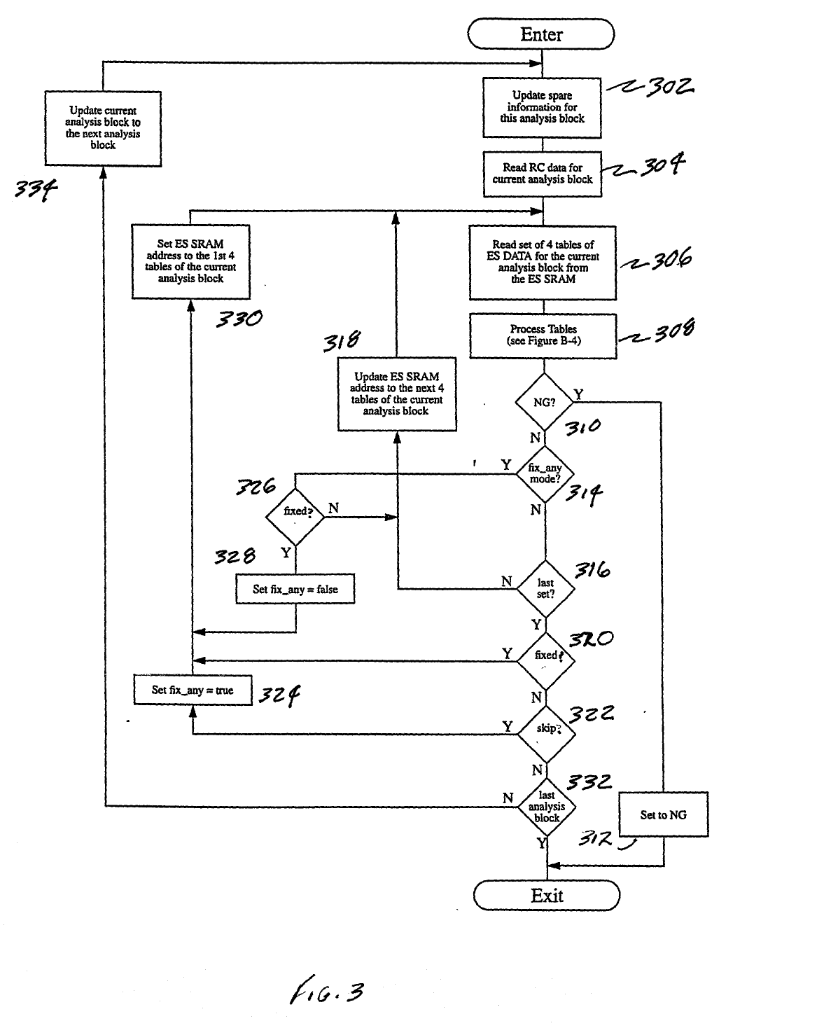

A flow diagram for the analysis portion of the routine is depicted in FIG. 3. Although not strictly required, the routine begins at step 302 by determining (or updating) information relating to the functionality of the various row and column spares that form the redundant circuitry for the analysis block currently being analyzed. The spare functionality information may be stored in memory, e.g., in the ES SRAM, on a sub-block 202 basis. If the spare functionality information is stored in this manner, then step 302 should further include the step of grouping together related spare functionality information gathered from amongst the various sub-blocks 202.

The grouping of related spare functionality information may be accomplished using logical “OR” functions. For example, for the analysis block shown in FIG. 2, functionality information relating to a spare row for each of the I/O sections 206 of a given set 204 should be logically OR'd together, since the spare row crosses each of the four I/O sections 206 shown of the set 204. Similarly, functionality information relating to a spare I/O (or column) for each of the rows in an I/O section 206 should be logically OR'd together, since the spare I/O crosses each of the rows in the I/O section 206.

After the spare functionality information for the current analysis block has been updated, the routine proceeds to step 304, where any stored repair code (RC) information for the current analysis block is read from memory. Preferably, the RC information is stored separately from the error storage information, e.g., in separate RC and ES SRAMs, respectively, but this storage arrangement is not strictly necessary. Steps 306 through 330 represent the main portion of the analysis routine. It is in these steps that the failed memory cell information for a given analysis block 102 is analyzed such that the appropriate repair codes for repairing the analysis block can be generated. After each analysis block is processed, a determination is made at step 332 whether all analysis blocks in the memory array have been processed. If so, the process ends; otherwise, information related to the next analysis block to be processed is updated at step 334, and the process repeats at step 302.

The main portion of the analysis routine utilizes a two-step approach. First, the routine attempts to repair those rows and/or I/Os of the analysis block that must be fixed in a particular manner—either by assigning a spare row or a spare I/O to repair the errors. Next, the routine attempts to repair those rows and/or I/Os that can be repaired in multiple ways—by assigning either type of available spare to repair the errors.

Although not expressly shown in the flow diagram, the various flags used by the routine are initialized to the following values prior to beginning the processing of a new analysis block:

| | |
|---|---|
| Fix_Any: | set to “N”; |
| Fixed: | set to “N”; |
| Skip: | set to “N”; |
| NG: | set to “N”; and |
| Last Set: | set to “N” (note: the value of this flag depends on the |
| | configuration of spares/sub-blocks/sets in the current analysis |
| | block 102). |

Processing of an analysis block begins at step 306 with the reading of ES data for the current analysis block, e.g, from the ES SRAM. Because the flag Fix_Any is initialized to “N”, the routine begins its analysis of the ES data by first processing the so-called “Must” errors first. Recall that “Must” errors represent memory cell failures that can only be repaired with a particular type of spare, i.e., either a spare row or spare I/O (or column), in this example. This phase of the analysis routine represents the first of the two-step approach described above.

Recall that the analysis block shown in FIG. 2 is comprised of eight sub-blocks 202 arranged into two sets 204 of four sub-blocks each. Each set includes two spare rows that are available to replace any of the 512 rows spanning across the four sub-blocks 202 of the set 204. Given this particular arrangement, the first four error storage tables are read at step 306 from the ES SRAM. These error storage tables correspond to the four sub-blocks 202 that make up the first set 204 of the analysis block 102. Other arrangements will require varying amounts of data to be read from the ES SRAM.

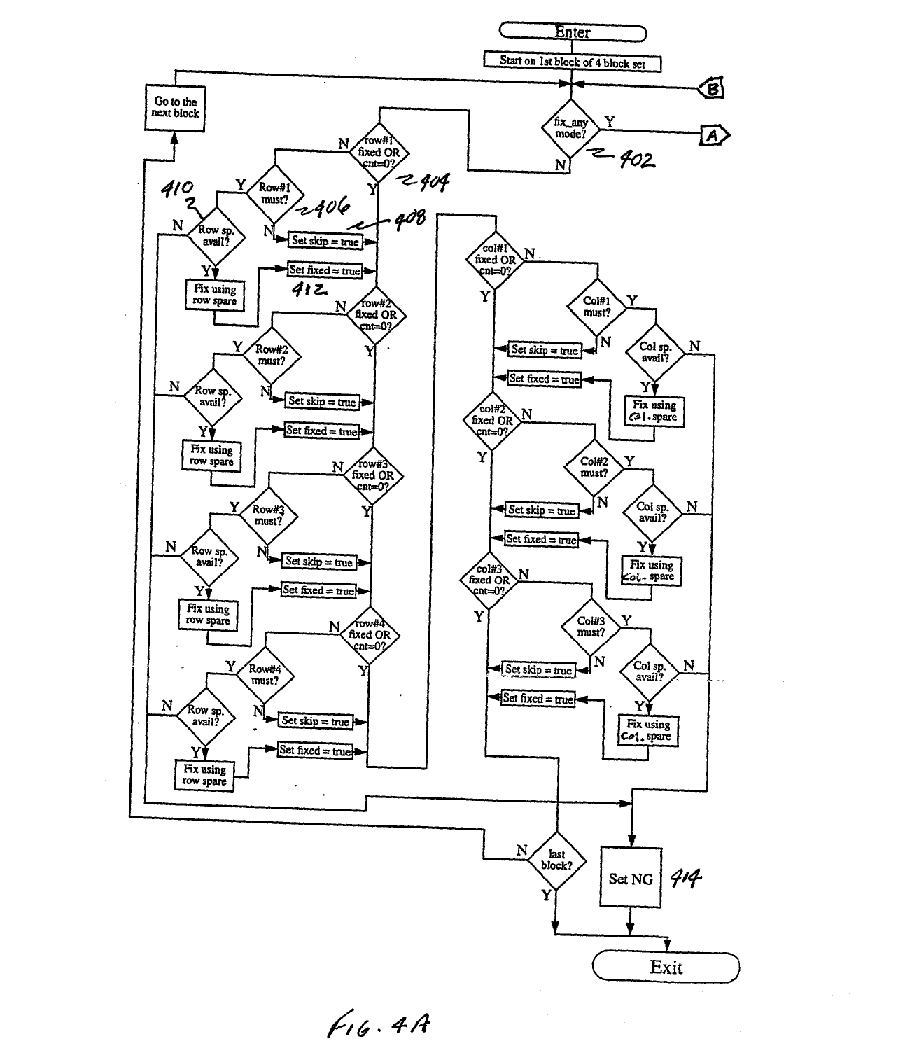

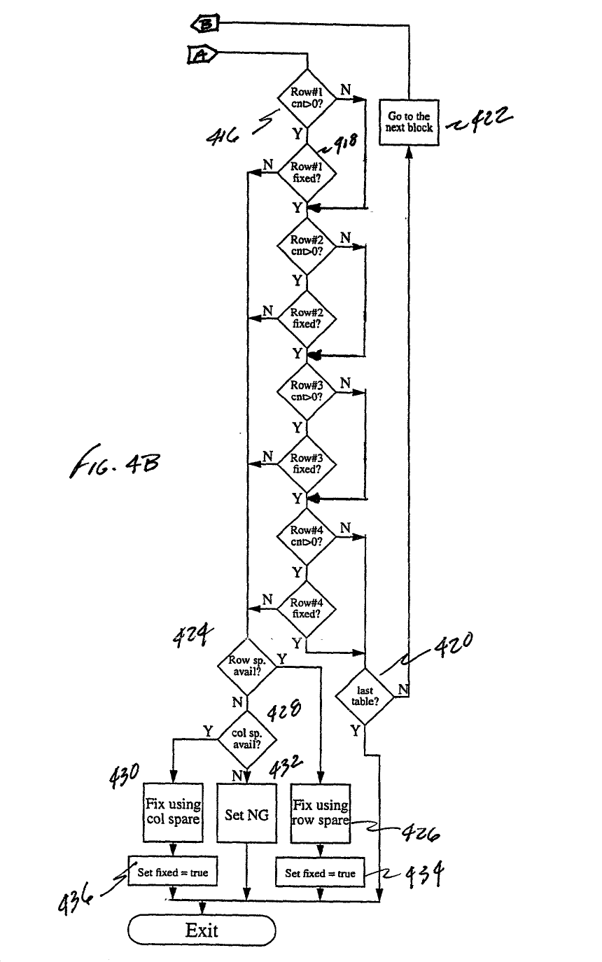

Next, the ES data read at step 306 is processed at step 308 using the repair routine illustrated in FIGS. 4A and 4B (described in detail below). Again, because the flag Fix_Any is initialized to “N”, the repair routine begins by first attempting to repair the so-called “Must” errors. The flags Skip, Fixed, and NG, once set in the repair routine, should be maintained throughout this phase of the analysis and passed back to the analysis portion of the routine depicted in FIG. 3. Recall that the flag Skip should be set to “Y” if an error is encountered that is not repaired; the flag Fixed should be set to “Y” if an error is repaired; and the flag NG should be set to “Y” if an error is encountered that cannot be repaired.

At step 310, control returns to the analysis portion of the routine, where the current state of the NG flag is tested. If the NG flag has been set to “Y”, the routine proceeds to step 312, where the memory array is identified as being not repairable. The memory array need not be further analyzed once this determination is made, and the analysis and repair routine ends.

If the flag NG is set to “N” at step 310, the routine proceeds to step 314, where the current state of the Fix_Any flag is tested. As indicated above, this flag is set to “N” during the first phase of the two-step analysis so as to identify and repair “Must” errors before other identified errors.

Accordingly, during the first phase of the analysis, the routine proceeds to step 316, where a determination is made whether the current set 204 being processed is the last set 204 in the analysis block 102 to be analyzed. If the current set 204 being analyzed is not the last set to be processed in the analysis block, the routine proceeds to step 318, where the ES SRAM address is updated to access the next four error storage tables stored in the SRAM, corresponding to the next set 204 to be analyzed by the routine. Steps 306 through 318 are repeatedly executed until all sets 204 in the analysis block 102 have been processed for “Must” errors.

When it is determined at step 316 that the current set 204 being processed is the last set 204 in the current analysis block 102, the routine proceeds to step 320, where the current state of the Fixed flag is tested. If the Fixed flag is set to “Y”, indicating that a “Must” error was repaired by the repair routine at step 308, the process proceeds to step 330, where the ES SRAM address is updated to once again access the first four error storage tables stored in the ES SRAM. These error storage tables correspond to the first set 204 of the analysis block 102 currently being analyzed. Although not shown in the figure, the flags Skip and Fixed are re-initialized to “N” at step 330.

Steps 306 through 318 are again repeatedly executed until all sets 204 in the current analysis block 102 have been processed for “Must” errors. It will be understood that fixing any error in the analysis block can cause a previously skipped error (skipped because the identified error was not a “Must” error) to subsequently become a “Must” error. Therefore, processing of the analysis block for “Must” errors is repeated until no new errors are fixed by the repair routine.

When no new “Must” errors are fixed by the repair routine, the Fixed flag returned by the repair routine will remain set to its initial value of “N”. Consequently, when the Fixed flag is tested at step 320, the process will proceed to step 322, where the current state of the Skip flag is tested. This signifies the end of the first phase of the two-step approach in which “Must” errors are repaired before other types of errors.

If no errors were skipped during the first phase of the analysis, the process proceeds to step 332, where a determination is made whether the current analysis block 102 is the last analysis block to be processed in the memory array. If the current analysis block is the last analysis block to be processed, the routine ends; otherwise the routing proceeds to step 334; where the entire routine is repeated on the next analysis block in the memory array. Although not shown in the figure, the flags Skip, Fix_Any, and Fixed are re-initialized to “N” at step 334.

If errors were skipped during the first phase of the analysis, the value of the Skip flag returned by the repair routine will be set to “Y”. Consequently, when the flag is tested at step 322, the routine will proceed to step 324 where the Fix_Any flag is set to “Y”. This signifies the beginning of the second phase of the two-step approach, in which errors that can repaired by either type of available spare are processed by the repair routine.

After setting the Fix_Any flag to “Y”, the ES SRAM address is updated at step 330 to once again access the first four error storage tables stored in the ES SRAM. These error storage tables correspond to the first set 204 of the analysis block 102 currently being analyzed. The flags Skip, and Fixed are again initialized to “N”.

Steps 306 through 312 are executed in the second phase of the analysis in the same manner as during the first phase of the analysis. When the Fix_Any flag is tested at step 314, the routine will proceed to step 326, since the flag is set to “Y” while in the second phase of the analysis.

At step 326, the flag Fixed is tested to determine if any errors were fixed by the repair routine at step 308. If no errors were fixed, the routine proceeds to step 318, where the ES SRAM address is updated to access the next four error storage tables stored in the SRAM. These storage tables correspond to the next set 204 of the analysis block 102 to be processed by the routine. Sets 204 of the analysis block 102 are processed until a determination is made, at step 326, that an error in the analysis block has been repaired. Recall, that at this point in the routine, at least one error must exist in the analysis block, as the second phase of the analysis routine was entered only after it was determined at step 322 that an error was skipped during the first phase of the analysis.

When it is determined that an error in the analysis block has been repaired at step 326, the routine proceeds to step 328, where the Fix_Any flag is reset to “N”. The causes the routine to reenter the first phase of the analysis, where the routine searches for and attempts to repair “Must” errors—those errors that can only be repaired with one particular type of available spare.

Again, it will be understood that fixing any error in the analysis block during the second phase of analysis and repair can generate new “Must” errors. Choosing which of the errors in the second phase of the analysis is not a simple task. Accordingly, the described techniques do not to attempt to determine the best error to fix, but instead repair the first unfixed error encountered in the analysis block, and then return to the first phase of the analysis where possible new “Must” errors are detected and repaired. This approach leads to a simple and efficient that has negligible effect on the overall performance of the analysis and repair routine.

Alternatively, an attempt may be made during the second phase of the analysis to determine the type of memory spare that can repair the greatest number of remaining non-“Must” type errors. Making this determination can lead to improved manufacturing yields, but adds complexity to the routine and increases the analysis and repair time and storage requirements needed to effect memory repairs.

The above-described sequence of execution of the first and second phases of analysis and repair continues until: 1) the first phase completes without fixing a “Must” error and without skipping an unfixed error, or 2) it is determined that the memory area is not repairable (i.e., the NG flag being set to “Y”). Upon completion of the routine, the repair codes needed to replace the failed memory cells of the memory array being analyzed are stored in the RC SRAM.

### Repair Routine

FIGS. 4A and 4B depict a flow diagram of an exemplary repair routine for generating the repair codes needed to replace the failed memory cells of the memory array with spare cells. FIG. 4A depicts the steps executed when operating in the first phase of analysis and repair—where detected “Must” errors are repaired. FIG. 4B depicts the steps executed when operating in the second phase of analysis and repair—when errors other than “Must” type errors are repaired. The decision as to whether “Must” errors or other types of errors are processed occurs at step 402 of the routine, shown in FIG. 4A.

Before describing the repair routine in detail, it will be helpful to define certain terms used in the routine, and to make some general observations regarding the operation of the routine.

First, what constitutes a “Must” type of error can depend upon any number of variables, including, but not limited to: the size of the memory array being analyzed, the number of errors detected, the desired test yield, and the number of available spare rows and columns (or I/Os). According to a preferred embodiment, a “Must” error is defined as either: 1) an error detected in a given row of the analysis block, where the number of errors in the given row exceeds the number of available spare columns (or I/Os), or 2) an error detected in a given column (or I/O) of the analysis block, where the number of errors in the given column (or I/O) exceeds the number of available spare rows.

Second, the exemplary flow diagrams depicted in FIGS. 4A and 4B indicate that row errors are processed and repaired before column errors, but this need not be the case. For example, in the portion of the routine depicted in FIG. 4A, in which “Must” type errors are processed, every row and column entry in a error storage table is tested for errors, making the decision whether to start with row or column entries an arbitrary one. Whether row or column entries are first processed in the portion of the routine depicted in FIG. 4B, in which non-“Must” type errors are processed, depends on the error storage techniques applied. For example, the error storage techniques described in copending U.S. patent application Ser. No. 10/______, ensure that non-“Must” type errors have both row and column entries in the error storage table.

Accordingly, FIG. 4B, which reflects the application of these error storage techniques, shows only row entries in the table being tested for non-“Must” type errors, but this need not be the case. If the storing of failed memory cell information in the ES SRAM does not guarantee that non-“Must” type errors will have both row and column entries, the routine can be modified to search for the at least one non-“Must” type errors in both the row and column entries of the error storage table. Moreover, the routine can be modified to only search for non-“Must” type errors in the column entries of the error storage table if the storage of failed memory cell information in the ES SRAM so warrants.

Finally, FIGS. 4A and/or 4B depict four rows and three columns being processed for each sub-block 202 that forms a set 204 of an analysis block 102. It will be understood that the number of rows and columns processed in the repair routine depends upon the amount of failed memory cell information stored in the ES SRAM. Recall from above that each row of the ES SRAM may correspond to an error storage table. As described in copending U.S. patent application Ser. No. 10/______, each error storage table includes row and column entries for storing at least a portion of the total failed memory cell information.

The copending application further describes that for a sub-block 202, having two spare rows and one spare column, the number of table row entries needed to effect repairs is four—two entries for each available spare row, plus two entries for each intersection of the two available spare rows with the single available spare column, while the number of table column entries needed to effect repairs is three—one entry for the single available spare column, plus two entries for each intersection of the single available spare column with the two available spare rows. Thus, the number of rows and/or columns processed in FIGS. 4A and 4B is merely illustrative, and could be any number up to the total number of rows and columns in a given sub-block 202. The lesser the number of rows and columns to be processed, the more efficient and effective the repair routine becomes.

With these definitions and general observations in mind, the portion of the repair routine depicted in FIG. 4A will now be described in greater detail. As can be seen in the figure, each of the sub-blocks 202 that make up a given set 204 are processed sequentially in the routine. Each row and column entry in the error tables are processed in the same manner, so only the processing of row #1 will be described in detail.

Processing of the first ES table row (or column or I/O) entry begins at step 404, where it is determined whether the error identified in that table entry has already been repaired (i.e., fixed with a spare row or column), or whether the number of errors in the corresponding row is zero, and thus need not be repaired. If either of these conditions are true, the routine moves on to process the next row (and then column) entry in the error storage table until all row and column entries in the table have been processed. If neither of the conditions is true, the routine proceeds to step 406, where the failure is determined to be either a “Must” type or other type of error. Recall that according to a preferred embodiment, if the number of errors detected in the row exceeds the number of available spare columns, the error will be deemed a “Must” error.

If the error is not a “Must” type error, the error is skipped (since this portion of the routine processes only “Must” type errors) and the routine proceeds to step 408 where the Skip flag is set to true. This indicates to the analysis routine shown in FIG. 3 that a detected error has been skipped, so that further processing in that routine can proceed accordingly. The routine then moves on to process the next row (and then column) entry in the error storage table until all row and column entries have been processed.

If the error is determined to be “Must” type error, the routine then proceeds to step 410, where a determination as to whether a spare row is available to repair the error. If a spare row is available, the available spare row is assigned to repair the error and the routine proceeds to step 412 where the Fixed flag is set to true. This indicates to the analysis routine that a detected error has been fixed, so that further processing in that routine can proceed accordingly. The routine then moves on to process the next row (and then column) entry in the error storage table until all row and column entries have been processed.

If no spare rows are available to repair the detected “Must” type error, the routine proceeds to step 414, where the flag NG is set to “Y”. This flag indicates to the analysis routine that the memory array being analyzed is not repairable, and all analysis and repair of array is halted. When each of the sub-blocks 202 in the current set 204 of the analysis block 102 has been processed, the routine returns control to the analysis portion of the routine at step 308.

The portion of the repair routine depicted in FIG. 4B will now be described in greater detail. Recall that this portion of the routine detects and attempts to repair one of the at least one errors skipped while processing “Must” errors in the portion of the routine depicted in FIG. 4A. Because each of the row (or perhaps column or I/O) entries is processed in the same manner, only the processing row #1 will described in detail. This portion of the routine begins at step 416, where it is determined if an error has been detected in row one. If an error has been detected, the routine proceeds to step 418, where it is determined if the detected error has already been repaired. If either no error is detected in the first row entry or a detected error in the first row entry has already been repaired, the routine moves on to process the remaining row (or column or I/O) entries in error storage table, until all entries have been processed.

Alternatively, if the applied error storage techniques can ensure that the row (or column or I/O) entries below a first row (or column or I/O) entry in the error storage table having no errors, also contains no errors, then the processing of further row (or column or I/O) entries may be skipped. The routine can then proceed directly to steps 420 and 422, where the next sub-block 202 in the current set 204 of the analysis block 102 is processed.

If it is determined at step 418 that the detected error has not already been repaired, then the routine proceeds to step 424, where it is determined whether a row spare is available to repair the detected error. If a row spare is available, the error is repaired with the available spare at step 426 and the Fixed flag is set at step 434. If no row spares are available, the routine proceeds to step 428, where it is determined whether a column spare is available to repair the detected error. If a column spare is available, the error is repaired with the available spare at step 430 and the Fixed flag is again set at step 436. If neither a row or column spare is available to repair the detected error, the NG flag is set to “Y” at step 432, and control returns to the analysis portion of the routine.

Certain terms have been used for convenience in describing the exemplary embodiments, but should not be used to limit the general concepts described herein. For example, any specific reference to “row” or “column” portions of memory or types of memory spares can be interpreted to embrace either of these portions of memory or types of memory spares. In the case of memory spares, the specific terms represent complementary types of memory spares in that if one type of memory spare is not used to repair a given memory cell location, the other complementary type of memory spare may be used to repair the location.

Furthermore, the terms “repair” or “repairing” not only include the replacement of failed memory cells with spare cells, but also include the generation of repair information that may be stored, e.g., in the RC SRAM, for later use in replacing failed memory cells with spare cells. Moreover, the terms “cell” and “memory cell” can be interpreted to represent one or several memory cells or locations in the memory. Finally, the terms “Y” and “true” and “N” and “false” are used interchangeably throughout the description and claims to describe the state of various test conditions that occur in described routines.

Various aspects have been described in connection with a number of exemplary embodiments. To facilitate an understanding of these embodiments, many aspects were described in terms of sequences of actions that may be performed by elements of a computer system or micro-controller. For example, it will be recognized that in each of the embodiments, the various actions could be performed by specialized circuits (e.g., discrete logic gates interconnected to perform a specialized function), by program instructions being executed by one or more processors, or by a combination of both.

Moreover, the exemplary embodiments can be considered part of any form of computer readable storage medium having stored therein an appropriate set of computer instructions that would cause a processor to carry out the techniques described herein. Thus, the various aspects may be embodied in many different forms, and all such forms are contemplated to be within the scope of what has been described. For each of the various aspects, any such form of embodiment may be referred to herein as “logic configured to” perform a described action, or alternatively as “logic that” performs a described action.

Although various exemplary embodiments have been described, it will be understood by those of ordinary skill in this art that these embodiments are merely illustrative and that many other embodiments are possible. The intended scope of the invention is defined by the following claims rather than the preceding description, and all variations that fall within the scope of the claims are intended to be embraced therein.

What is claimed is:

1. A method for analyzing and repairing memory, the method comprising the steps of:
determining if failed memory cells detected in at least a portion of memory must be repaired using only one of a plurality of types of memory spares or may be repaired using any of the plurality of types of memory spares;
repeatedly repairing failed memory cells that must be repaired using only one of the plurality of types of memory spares, skipping any failed memory cells that may be repaired using any of the plurality of types of memory spares, until either no new errors that must be repaired are repaired and no failed memory cells are skipped or the memory is determined to not be repairable;
repairing at least one of any failed memory cells skipped when repairing failed memory cells that must be repaired; and
repeating the steps of determining if failed memory cells must be repaired and repeatedly repairing failed memory cells that must be repaired whenever at least one skipped failed memory cell is repaired.

2. The method of claim 1, wherein a first type of the plurality of types of memory spares is capable of repairing one of a row and a column portion of memory and a second complementary type of the plurality of types of memory spares is capable of repairing the other of the row and column portions of memory.

3. The method of claim 2, wherein failed memory cells that must be repaired include failed memory cells in a respective row or column portion of memory having a total number of failed memory cells that exceeds a number of available complementary type memory spares.

4. The method of claim 1, wherein the at least a portion of memory is defined by:
logically dividing the memory into a number of analysis blocks, each analysis block completely including at least one of each type of the plurality of types of memory spares.

5. The method of claim 4, wherein the at least a portion of memory is defined by:
logically dividing each analysis block into a number of sub-blocks, each sub-block extending over an area of the respective analysis block corresponding to a range of memory cells each of the plurality of types of memory spares are capable of repairing.

6. The method of claim 5, further comprising the step of:
storing failed memory cell information for each sub-block as a separate addressable entry in memory.

7. The method of claim 6, wherein the failed memory cell information for each sub-block is stored in a portion of the memory being analyzed and repaired.

8. The method of claim 6, wherein each addressable entry in memory corresponds to an error storage table for a respective sub-block, each error storage table having row and column entries for storing information related to a number of failed memory cells detected in respective row and column portions of memory.

9. The method of claim 8, further comprising the step of:
reading the information related to the number of failed memory cells detected in respective row and column portions of memory from at least one error storage table stored in memory;
wherein the failed memory cells detected in the at least a portion of memory are located in sub-blocks corresponding to the at least one error storage table from which the information related to the number of failed memory cells is read.

10. The method of claim 9, further comprising the step of:
performing each of the steps of the method on separate portions of the memory until either all failed memory cells detected in the memory have been repaired or the memory is determined to not be repairable.

11. The method of claim 10, wherein the performing of each of the steps of the method on separate portions of the memory occurs at the same time for each separate portion.

12. The method of claim 8, wherein the step of repeatedly repairing failed memory cells that must be repaired using only one of the plurality of types of memory spares comprises the steps of:
determining if a row or column entry in the at least one error storage table is empty or if an error identified by the row or column entry has been repaired;
if neither the row or column entry is empty nor the identified error has been repaired, then determining if the identified error must be repaired, otherwise determining if a next row or column entry in the at least one error storage table is empty or if an error identified by next the row or column entry has been repaired;
if the identified error must be repaired, then determining if a spare of the only one of the plurality of types of memory spares is available, otherwise skipping repairing the identified error and determining if a next row or column entry in the at least one error storage table is empty or if an error identified by next the row or column entry has been repaired; and
if a spare of the only one of the plurality of types of memory spares is available, then repairing the identified error with a spare of the only one of the plurality of types of memory spares and determining if a next row or column entry in the at least one error storage table is empty or if an error identified by next the row or column entry has been repaired, otherwise determining the memory to not be repairable;
wherein the step of determining if a row or column entry in the at least one error storage table is empty or if an error identified by the row or column entry has been repaired is repeated until all row and column entries in the at least one error storage table have been processed.

13. The method of claim 8, wherein the step of repairing at least one of any failed memory cells skipped when repairing failed memory cells that must be repaired comprises the step of:
repairing only a first detected failed memory cell of the at least one of any skipped failed memory cells.

14. The method of claim 13, wherein the step of repairing only a first detected failed memory cell comprises the step of:
determining if a row or column entry in the at least one error storage table is empty;
if the row or column entry is not empty, then determining if an error identified by the row or column entry has been repaired, otherwise determining if a next row or column entry in the at least one error storage table is empty;
if the identified error has not been repaired, then determining if a first type of the plurality of types of memory spares is available, otherwise determining if a next row or column entry in the at least one error storage table is empty;
if a first type of the plurality of types of memory spares is available, then repairing the identified error with a spare of the first type, otherwise determining if a second complementary type of the plurality of types of memory spares is available; and
if a second type of the plurality of types of memory spares is available, then repairing the identified error with a spare of the second type, otherwise determining the memory to not be repairable;
wherein the step of determining if a row or column entry in the at least one error storage table is empty is repeated until at least all row entries or all column entries in the at least one error storage table have been processed.

15. The method of claim 14, wherein if it is determined that any row or column entry in the at least one error storage table is empty, next entries of the type that is empty need not be processed.

16. The method of claim 2, wherein the row portion of memory includes at least one row of memory and the column portion of memory includes at least one column of memory.

17. The method of claim 2, wherein the column portion of memory includes at least one input/output (I/O) device, the at least one I/O device providing an input and output path for at least one column of memory.

18. The method of claim 1, wherein the step of repairing at least one of any failed memory cells skipped when repairing failed memory cells that must be repaired comprises the steps of:
determining which type of the plurality of types of memory spares is capable of repairing a greatest number of failed memory cells that may be repaired using any of the plurality of types of memory spares; and
replacing the greatest number of failed memory cells with an available spare of the determined type.

19. The method of claim 1, wherein prior to determining if failed memory cells detected in at least a portion of memory must be repaired, the method further comprises the steps of:
determining if any of the plurality of types of memory spares in the at least a portion of memory is non-functional; and
grouping together information related to non-functional memory spares based on an arrangement of the plurality of types of memory spares in the at least a portion of memory.

20. The method of claim 19, wherein the step of grouping together information related to non-functional memory spares comprises the step of:
logically ORing together the information related to non-functional memory spares for a number of portions of the at least a portion of memory if the portions are capable of being repaired by at least one of a respective type of the plurality of types of memory spares.

21. An apparatus for analyzing and repairing memory, the apparatus comprising:
logic that determines if failed memory cells detected in at least a portion of memory must be repaired using only one of a plurality of types of memory spares or may be repaired using any of the plurality of types of memory spares;
logic that repeatedly repairs failed memory cells that must be repaired using only one of the plurality of types of memory spares, skipping any failed memory cells that may be repaired using any of the plurality of types of memory spares, until either no new errors that must be repaired are repaired and no failed memory cells are skipped or the memory is determined to not be repairable;
logic that repairs at least one of any failed memory cells skipped when repairing failed memory cells that must be repaired; and
logic that determines if failed memory cells must be repaired and repeatedly repairs failed memory cells that must be repaired whenever at least one skipped failed memory cell is repaired.

22. The apparatus of claim 21, wherein a first type of the plurality of types of memory spares is capable of repairing one of a row and a column portion of memory and a second complementary type of the plurality of types of memory spares is capable of repairing the other of the row and column portions of memory.

23. The apparatus of claim 22, wherein failed memory cells that must be repaired include failed memory cells in a respective row or column portion of memory having a total number of failed memory cells that exceeds a number of available complementary type memory spares.

24. The apparatus of claim 21, further comprising:
logic that logically divides the memory into a number of analysis blocks, each analysis block completely including at least one of each type of the plurality of types of memory spares.

25. The apparatus of claim 24, further comprising:
logic that logically divides each analysis block into a number of sub-blocks, each sub-block extending over an area of the respective analysis block corresponding to a range of memory cells each of the plurality of types of memory spares are capable of repairing.

26. The apparatus of claim 25, further comprising:
logic that stores failed memory cell information for each sub-block as a separate addressable entry in memory.

27. The apparatus of claim 26, wherein the failed memory cell information for each sub-block is stored in a portion of the memory being analyzed and repaired.

28. The apparatus of claim 26, further comprising:
an error storage table for each addressable entry in memory corresponding to a respective sub-block, each error storage table having row and column entries for storing information related to a number of failed memory cells detected in respective row and column portions of memory.

29. The apparatus of claim 28, further comprising:
logic that reads the information related to the number of failed memory cells detected in respective row and column portions of memory from at least one error storage table stored in memory;
wherein the failed memory cells detected in the at least a portion of memory are located in sub-blocks corresponding to the at least one error storage table from which the information related to the number of failed memory cells is read.

30. The apparatus of claim 29, further comprising:
logic that determines if failed memory cells detected in separate portions of the memory have been repaired until either all failed memory cells detected in the memory have been repaired or the memory is determined to not be repairable.

31. The apparatus of claim 30, wherein the logic determines if failed memory cells have been repaired in the separate portions of the memory at the same time.

32. The apparatus of claim 28, further comprising:
logic that determines if a row or column entry in the at least one error storage table is empty or if an error identified by the row or column entry has been repaired;
logic that determines if the identified error must be repaired, when neither the row or column entry is empty nor the identified error has been repaired;
logic that determines if a next row or column entry in the at least one error storage table is empty or if an error identified by next the row or column entry has been repaired, when either the row or column entry is empty nor the identified error has been repaired;
logic that determines if a spare of the only one of the plurality of types of memory spares is available, when the identified error must be repaired
logic that skips repairing the identified error and determines if a next row or column entry in the at least one error storage table is empty or if an error identified by next the row or column entry has been repaired, when the identified error need not be repaired;
logic that repairs the identified error with a spare of the only one of the plurality of types of memory spares and determines if a next row or column entry in the at least one error storage table is empty or if an error identified by next the row or column entry has been repaired, when a spare of the only one of the plurality of types of memory spares is available; and
logic that determines the memory to not be repairable, when a spare of the only one of the plurality of types of memory spares is not available.

33. The apparatus of claim 28, wherein the logic that repairs at least one of any failed memory cells skipped when repairing failed memory cells that must be repaired comprises:
logic that repairs only a first detected failed memory cell of the at least one of any skipped failed memory cells.

34. The apparatus of claim 33, wherein the logic that repairs only a first detected failed memory cell comprises:
logic that determines if a row or column entry in the at least one error storage table is empty;
logic that determines if an error identified by the row or column entry has been repaired, when the row or column entry is not empty;
logic that determines if a next row or column entry in the at least one error storage table is empty, when the row or column entry is empty;
logic that determines if a first type of the plurality of types of memory spares is available, when the identified error has not been repaired;
logic that determines if a next row or column entry in the at least one error storage table is empty, when the identified error has been repaired;
logic that repairs the identified error with a spare of the first type, when a spare of the first type is available;
logic that determines if a second complementary type of the plurality of types of memory spares is available, when a spare of the first type is not available;
logic that repairs the identified error with a spare of the second type, when a spare of the second type is available; and
logic that determines the memory to not be repairable, when a spare of the second type is not available.

35. The apparatus of claim 34, wherein if it is determined that any row or column entry in the at least one error storage table is empty, next entries of the type that is empty need not be processed.

36. The apparatus of claim 22, wherein the row portion of memory includes at least one row of memory and the column portion of memory includes at least one column of memory.

37. The apparatus of claim 22, wherein the column portion of memory includes at least one input/output (I/O) device, the at least one I/O device providing an input and output path for at least one column of memory.

38. The apparatus of claim 21, wherein the logic that repairs at least one of any failed memory cells skipped when repairing failed memory cells that must be repaired comprises:
logic that determines which type of the plurality of types of memory spares is capable of repairing a greatest number of failed memory cells that may be repaired using any of the plurality of types of memory spares; and
logic that replaces the greatest number of failed memory cells with an available spare of the determined type.

39. The apparatus of claim 21, further comprising:
logic that determines if any of the plurality of types of memory spares in the at least a portion of memory is non-functional; and
logic that groups together information related to non-functional memory spares based on an arrangement of the plurality of types of memory spares in the at least a portion of memory.

40. The apparatus of claim 39, wherein the logic that groups together information related to non-functional memory spares comprises:
logic that ORs together the information related to non-functional memory spares for a number of portions of the at least a portion of memory if the portions are capable of being repaired by at least one of a respective type of the plurality of types of memory spares.
